(19) United States
(12) Patent Application Publication
(10) Pub. No.: US 2018/0211849 A1
(43) Pub. Date: Jul. 26, 2018

(54) SUBSTRATE PROCESSING APPARATUS, SUBSTRATE PROCESSING SYSTEM AND SUBSTRATE PROCESSING METHOD

(71) Applicant: EBARA CORPORATION, Tokyo (JP)

(72) Inventors: Itsuki KOBATA, Tokyo (JP); Keita YAGI, Tokyo (JP); Yoichi SHIOKAWA, Tokyo (JP)

(21) Appl. No.: 15/745,694

(22) PCT Filed: Jul. 6, 2016
(86) PCT No.: PCT/JP2016/069998

§ 371 Date: Jan. 17, 2018

(30) Foreign Application Priority Data
Jul. 23, 2015 (JP) 2015-145960

(51) Int. Cl. H01L 21/67; H01L 21/306; H01L 21/3105; H01L 21/321; H01L 21/66

(52) U.S. Cl. CPC H01L 21/6708; H01L 21/30625; H01L 22/26; H01L 21/67253; H01L 21/3212; H01L 21/31053

(57) ABSTRACT

The invention performs optimum processing even when process requirements vary in the middle of a substrate processing process. A method is provided whereby a substrate is processed by causing the substrate and a catalyst to contact each other in the presence of a processing liquid. Such a method includes a step of processing the substrate under a predetermined processing condition for processing the substrate at a high speed and a step of changing the processing condition so as to process the substrate at a low speed during processing of the same substrate.

### TECHNICAL FIELD

The present invention relates to a substrate processing apparatus, a substrate processing system and a substrate processing method.

### BACKGROUND ART

In manufacture of semiconductor devices, a chemical mechanical polishing (CMP) apparatus is known which polishes a substrate surface. In the CMP apparatus, a polishing pad is pasted to a top surface of a polishing table to form a polishing surface. The CMP apparatus presses a surface to be polished of a substrate held by a top ring against the polishing surface and rotates the polishing table and the top ring while supplying slurry as a polishing liquid to the polishing surface. This causes the polishing surface and the surface to be polished to relatively slidingly move, and the surface to be polished is thereby polished.

Here, regarding flattening techniques including CMP, there are a wide variety of materials to be polished and requirements for polishing performance (e.g., flatness, polishing damage, and further productivity) are becoming stricter and stricter. Under such a background, new flattening methods are also being proposed and a catalyst referred etching (hereinafter CARE) method is also one of such methods. According to the CARE method, in the presence of a processing liquid, a reactive seed for reaction with a surface to be processed is generated from the processing liquid only in the vicinity of a catalyst material, the catalyst material and the surface to be processed are caused to approach or contact each other, and it is thereby possible to cause etching reaction to be selectively produced on the surface to be processed on the approaching surface or contacting surface with the catalyst material. For example, on a surface to be processed including convex and concave portions, convex portions can be selectively etched by causing the convex portions and the catalyst material to approach or contact each other and the surface to be processed can be flattened. The present CARE method has been initially proposed in flattening of next-generation substrate materials for which highly efficient flattening using CMP is not easy because SiC or GaN is chemically stable (e.g., PTLs 1 to 4 below). However, it has been confirmed in recent years that processing is possible even with silicon oxides or the like and the CARE method is possibly applicable to semiconductor device materials such as a silicon oxide film on a silicon substrate (e.g., PTL 5 below).

### CITATION LIST

### Patent Literature

PTL 1: Japanese Patent Application Laid-Open No. 2008-121099

PTL 2: Japanese Patent Application Laid-Open No. 2008-136983

PTL 3: Japanese Patent Application Laid-Open No. 2008-166709

PTL 4: Japanese Patent Application Laid-Open No. 2009-117782

PTL 5: WO/2013/084934

### SUMMARY OF INVENTION

### Technical Problem

However, when the present CARE method is applied to flattening of a semiconductor material on a silicon substrate, processing performance equivalent to that of CMP (chemical mechanical polishing) which has been a representative method in the present step so far is required. Uniformity at a wafer level or a chip level is required for an etching speed and an etching amount in particular. Furthermore, equivalent flattening performance is also required, and these requirements are becoming stricter and stricter as the process generation advances. In a flattening step of a semiconductor material on a normal silicon substrate, it is often the case that a plurality of materials are simultaneously removed and flattened and similar processes are required also for a substrate processing apparatus using the CARE method.

In a substrate processing process accompanied by flattening of an interface between different types of films, when films to be processed differ at an initial stage and at a final stage of the process or when process requirements differ, process performance such as flatness of a substrate, defects or productivity such as throughput may not always be sufficient at an initial stage and at a final stage of the substrate processing process under identical processing conditions.

### Solution to Problem

According to an embodiment of the present invention, a method for processing a substrate while bringing a catalyst into contact with the substrate in the presence of a processing liquid is provided. Such a method includes a step of processing the substrate under a predetermined processing condition for processing the substrate at a high speed and a step of changing the processing condition so as to process the substrate at a low speed during processing of the same substrate. According to such an embodiment, for example, when films to be processed differ at an initial stage and at a final stage of the substrate processing process or when process requirements differ or the like, the substrate can be processed under optimum conditions respectively.

According to another embodiment of the present invention, a method for processing a substrate while bringing a catalyst into contact with the substrate containing SiO₂ in the presence of a processing liquid is provided. Such a method includes a step of supplying a hydrofluoric acid solution to a surface of the substrate and etching SiO₂ of the substrate using the hydrofluoric acid solution. According to such an embodiment, it is possible to jointly use isotropic etching using the hydrofluoric acid solution and etching using the catalyst and the processing liquid, and thereby speedily process the substrate.

### BRIEF DESCRIPTION OF DRAWINGS

FIG. 1 is a schematic plan view of a substrate processing apparatus of a substrate processing system as an embodiment;

FIG. 2 is a side view of the substrate processing apparatus shown in FIG. 1;

FIG. 3 is a schematic side view illustrating components of a catalyst holding section as an embodiment;

FIG. 4 is a schematic side view illustrating components of the catalyst holding section as an embodiment;

FIG. 5 is a schematic bottom view illustrating the components shown in FIG. 4;

FIG. 6 is a schematic side view illustrating components of the catalyst holding section as an embodiment;

FIG. 7 is a schematic side view of the catalyst holding section as an embodiment;

FIG. 8 is a schematic side view illustrating the catalyst holding section as an embodiment;

FIG. 9 is a schematic side view of a substrate processing apparatus as an embodiment;

FIG. 10 is a schematic side view of a substrate processing apparatus as an embodiment;

FIG. 11 is a graph illustrating an etching speed of an SiO₂ substrate when a voltage to be applied to a catalyst is changed using a platinum catalyst with various processing liquids set to pH=3;

FIG. 12 is a graph illustrating an etching speed of SiO₂ when a voltage to be applied to the catalyst is changed using a platinum catalyst and a chromium catalyst with a processing liquid set to pH=7;

FIG. 13 is a graph illustrating an etching speed of SiO₂ when a voltage to be applied to the catalyst is changed using a nickel catalyst with a processing liquid set to various pHs;

FIG. 14 is a graph illustrating an etching speed of SiO₂ when a voltage to be applied to the catalyst is changed using a platinum catalyst with a processing liquid set to various pHs;

FIG. 15 is a schematic side view illustrating a state in an initial stage of a flattening process in an STI step as an embodiment;

FIG. 16 is a schematic side view illustrating a state in a final stage of the flattening process in the STI step as an embodiment;

FIG. 17 is a diagram illustrating a processing flow in the STI step shown in FIG. 15 and FIG. 16; and

FIG. 18 is a diagram illustrating another example of applying an etching process to a wafer Wf by changing an etching processing condition during processing on a wafer as an embodiment.

### DESCRIPTION OF EMBODIMENTS

Hereinafter, embodiments of a substrate processing apparatus, a substrate processing system including the substrate processing apparatus and a substrate processing method according to the present invention will be described along with the accompanying drawings. The drawings and the following description will describe only characteristic parts of the described embodiments and omit descriptions of other components. Features of the other embodiments and publicly known configurations can be adopted for the omitted components.

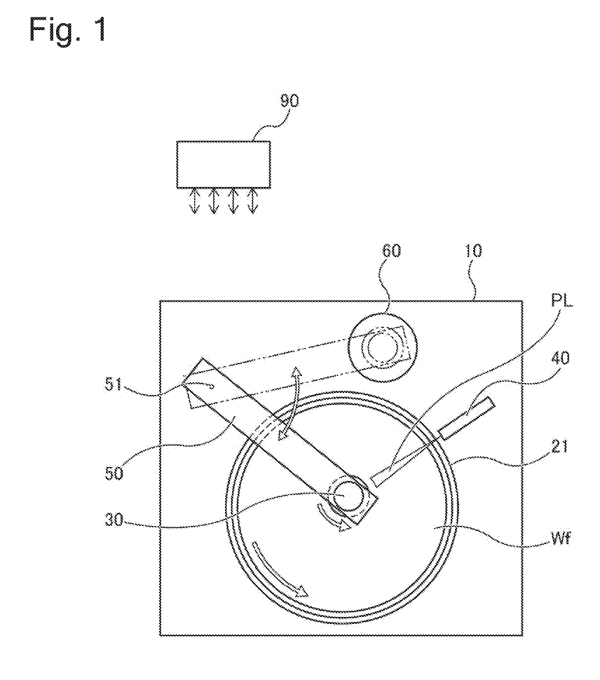

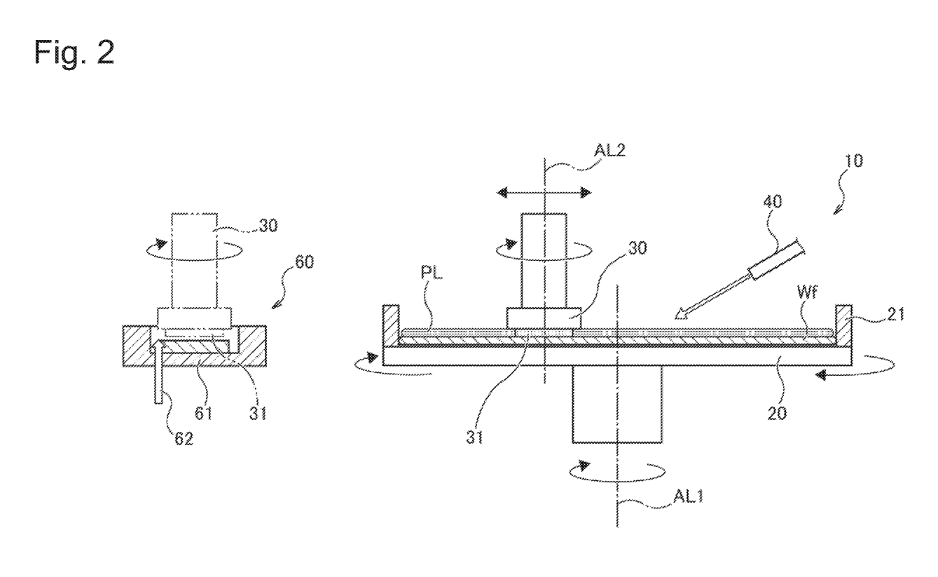

FIG. 1 is a schematic plan view of a substrate processing apparatus 10 of a substrate processing system as an embodiment of the present invention. FIG. 2 is a side view of the substrate processing apparatus 10 shown in FIG. 1. The substrate processing apparatus 10 is an apparatus that performs etching processing on a semiconductor device material (region to be processed) on a substrate using a CARE method. The substrate processing system is provided with the substrate processing apparatus 10, a substrate cleaning section configured to clean the substrate and a substrate transporting section that transports the substrate. The substrate processing system may also be provided with a substrate drying section (not shown) if necessary. The substrate transporting section is configured so as to be able to transport a substrate in a wet state and a substrate in a dry state separately. Depending on the type of a semiconductor material, it may be possible to perform a process using conventional CMP before or after a process by the present substrate processing apparatus, and a CMP apparatus may be thereby further provided. Furthermore, the substrate processing system may also include a chemical vapor deposition (CVD) apparatus, a sputtering apparatus, a plating apparatus and a film formation apparatus such as a coater apparatus. In the present embodiment, the substrate processing apparatus 10 is configured as a unit formed separately from the CMP apparatus. Since the substrate cleaning section, the substrate transporting section and the CMP apparatus are known techniques, illustrations and descriptions thereof will be omitted below.

The substrate processing apparatus 10 shown in FIG. 1 is provided with a substrate holding section 20, a catalyst holding section 30, a processing liquid supply section 40, a swing arm 50, a conditioning section 60 and a control section 90. The substrate holding section 20 is configured so as to hold a wafer Wf as a type of substrate. In the present embodiment, the substrate holding section 20 holds the wafer Wf in such a way that the surface to be processed of the wafer Wf faces up. In the present embodiment, the substrate holding section 20 is provided with a vacuum suction mechanism including a vacuum suction plate that vacuum suctions a reverse side of the wafer Wf (surface on the side opposite to the surface to be processed) as a mechanism for holding the wafer Wf. Regarding a vacuum suction scheme, either a point suction scheme using a suction plate having a plurality of suction holes connected to a vacuum line on a suction surface or a surface suction scheme having a groove (e.g., concentric form) on the suction surface for sucking through a connection hole to a vacuum line provided in the groove may be used. Furthermore, a backing member may be pasted to the suction plate surface for stabilization of the suction state and the wafer Wf may be suctioned via the backing member. However, the mechanism for holding the wafer Wf may be any publicly known mechanism, and may be, for example, a clamp mechanism for clamping the front side and reverse side of the wafer Wf at at least one part of a peripheral edge of the wafer Wf or a roller chuck mechanism for holding a side face of the wafer Wf at at least one part of the peripheral edge of the wafer Wf Such a substrate holding section 20 is configured so as to be rotatable around an axis AL1 by a drive section motor or actuator (not shown). In this drawing, the substrate holding section 20 is provided with a wall portion 21 extending upward in the vertical direction over the whole circumferential direction outside a region for holding the wafer Wf. This makes it possible to hold a processing liquid PL within a wafer surface, and as a result, to reduce the amount of the processing liquid PL used. Note that although the wall portion 21 is fixed to an outer perimeter of the substrate holding section 20 in the drawing, the wall portion 21 may be configured separately from the substrate holding section. In that case, the wall portion 21 may move upward or downward. With upward or downward motion enabled, it is possible to change the amount of the processing liquid PL held and efficiently discharge the cleaning liquid out of the wafer Wf by lowering the wall portion 21 when, for example, cleaning the substrate surface after etching processing.

The catalyst holding section 30 of the embodiment shown in FIG. 1 and FIG. 2 are configured so as to hold a catalyst 31 at its bottom end. In the present embodiment, the catalyst 31 is smaller than the wafer Wf. That is, a projection area of the catalyst 31 when projected from the catalyst 31 toward the wafer Wf is smaller than the area of the wafer Wf. The catalyst holding section 30 is configured so as to be rotatable around an axis AL2 by a drive section, that is, actuator (not shown). Furthermore, a motor or air cylinder to cause the catalyst 31 of the catalyst holding section 30 to make sliding contact with the wafer Wf is provided in the swing arm 50 (not shown) which will be described later. Next, the processing liquid supply section 40 is configured to supply a processing liquid PL to the surface of the wafer Wf. Here, although FIG. 2 shows only one processing liquid supply section 40, a plurality of processing liquid supply sections 40 may be disposed, and in such a case, the respective processing liquid supply sections may supply different processing liquids PL. When the substrate processing apparatus 10 cleans the surface of the wafer Wf after etching processing, the processing liquid supply section 40 may supply a chemical liquid for cleaning or water. Furthermore, the processing liquid supply section 40 may be configured so as to supply the processing liquid PL from the surface of the catalyst 31 through the interior of the catalyst holding section 30 as will be described later. Next, the swing arm 50 is configured to be swingable around a rotation center 51 through a drive section, that is, an actuator (not shown) and also configured to be movable upward or downward. The catalyst holding section 30 is rotatably attached at a distal end (an end on the side opposite to the rotation center 51) of the swing arm 50.

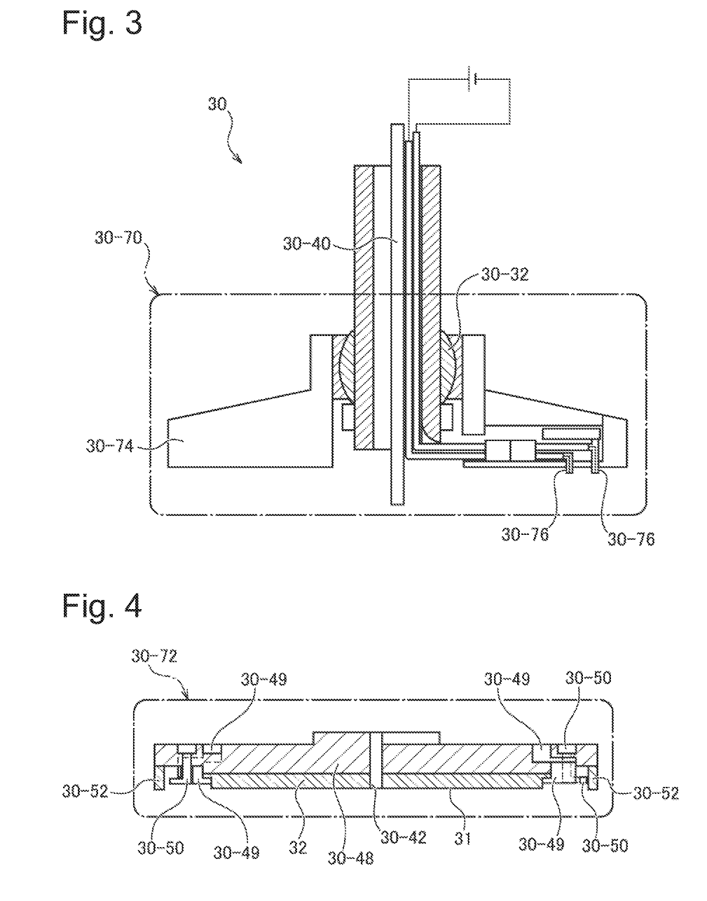

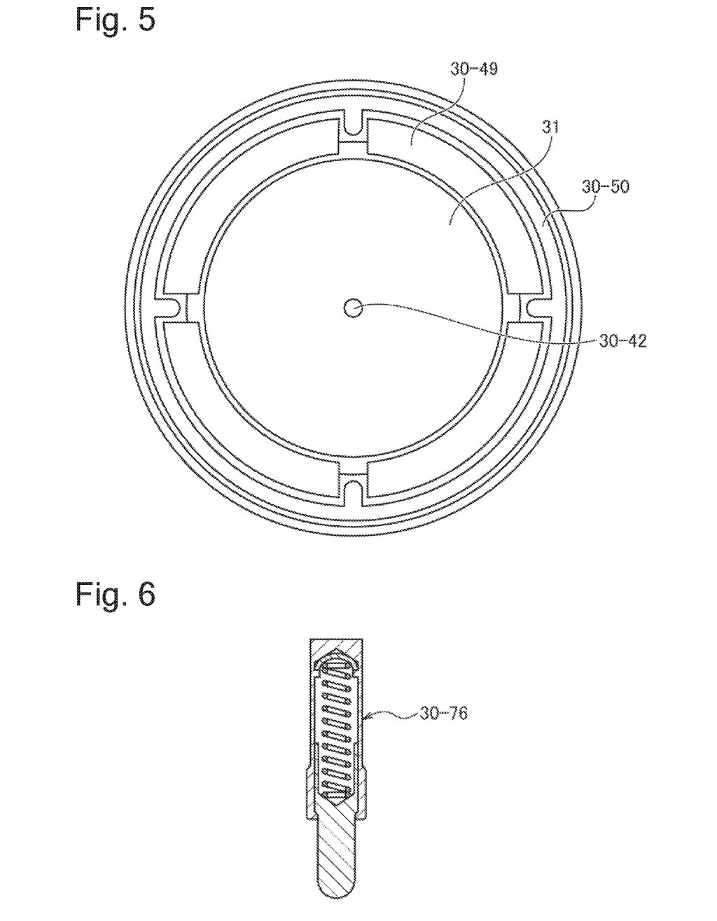

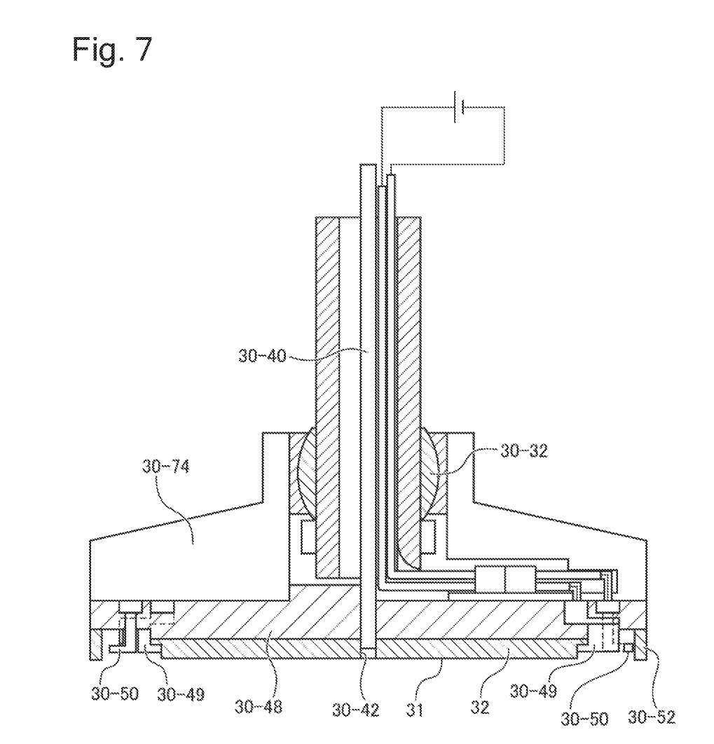

FIG. 3, FIG. 4, FIG. 6 and FIG. 7 are schematic cross-sectional side views illustrating a configuration of the catalyst holding section 30 as an embodiment according to the present disclosure. The catalyst holding section 30 in the present embodiment includes a disk holder part 30-70 shown in FIG. 3 and a catalyzer disk part 30-72 shown in FIG. 4, configured to be attachable to the disk holder part 30-70 and replaceable. FIG. 5 is a schematic plan view of the catalyzer disk part 30-72 shown in FIG. 4 seen from the catalyst 31 side. Note that FIG. 7 is a diagram illustrating a state in which these components are attached. As shown in FIG. 3, the disk holder part 30-70 includes a head 30-74. A processing liquid supply passage 30-40, a catalyst electrode wiring, and a counter electrode wiring extend at the center of the head 30-74. The head 30-74 is attached to the swing arm 50 via a gimbal mechanism 30-32 (e.g., spherical sliding bearing) in such a way that the head 30-74 is rotatable. A mechanism similar to that disclosed in, for example, Japanese Patent Application Laid-Open No. 2002-210650 can be adopted for the gimbal mechanism 30-32. As shown in FIG. 4 and FIG. 5, the catalyzer disk part 30-72 includes a catalyst holding member 32 (e.g., elastic member 32) and the catalyst 31 which is held by the catalyst holding member 32. As illustrated in the drawings, the catalyst 31 is electrically connected to the catalyst electrode 30-49. A counter electrode 30-50 is disposed outside the catalyst holding member 32. The catalyst wiring and the counter electrode wiring of the disk holder part 30-70 are electrically connected to the catalyst electrode 30-49 and the counter electrode 30-50 respectively when the catalyzer disk part 30-72 is connected. A voltage can be applied between the catalyst electrode 30-49 and the counter electrode 30-50 from an external power supply. In the catalyzer disk part 30-72, a wall portion 30-52 is formed outside the catalyst holding member 32 and the catalyst 31 and surrounding them from a certain distance. While the catalyst 31 is in contact with the wafer Wf, a processing liquid storage section for storing the processing liquid PL is defined by the wall portion 30-52. When the disk holder part 30-70 is connected to the catalyzer disk part 30-72, a contact probe 30-76 as shown in FIG. 6 is used for an electrical connection. When the disk holder part 30-70 is connected to the catalyzer disk part 30-72, the processing liquid supply passage 30-40 extends, penetrating the catalyst holding member 32 of the catalyzer disk part 30-72 up to a supply port 30-42 of the surface of the catalyst 31.

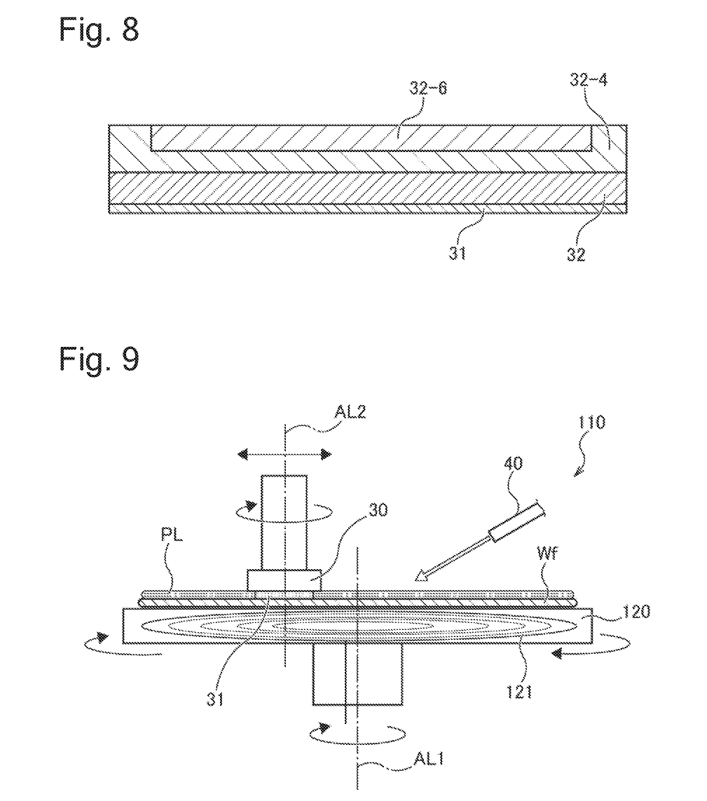

Any catalyst holding section 30 shown in the present disclosure can be provided with a catalyst temperature control mechanism for controlling temperature of the catalyst 31. A Peltier element can be used as the catalyst temperature control mechanism, for example. FIG. 8 is a schematic side view illustrating the catalyst holding section 30 as an embodiment. In the embodiment in FIG. 8, the catalyst 31 is held onto the surface of the elastic member 32. A support body 32-4 is disposed on the surface of the elastic member 32 on the side opposite to the side onto which the catalyst 31 is held. The Peltier element 32-6 is attached to the support body 32-4. The support body 32-4 is preferably a material of high thermal conductivity and can be formed of, for example, metal or ceramics. In the present embodiment, it is possible to increase an etching rate by raising the temperature of the catalyst 31 using the Peltier element 32-6. On the contrary, it is also possible to decrease the etching rate by cooling the catalyst 31 using the Peltier element 32-6. By cooling the catalyst 31, it is also possible to increase the hardness of the elastic member 32 and improve the property to eliminate steps by etching. By raising the temperature of the catalyst 31 at the etching start and cooling the catalyst 31 at a stage where etching has advanced to a certain degree, it is possible to improve both the etching rate and the property to eliminate steps. Note that the catalyst temperature control mechanism shown in FIG. 8 may also be applied to the catalyst holding section 30 shown in FIG. 3 to FIG. 7.

In the embodiment shown in FIGS. 1 and 2, the conditioning section 60 is configured to condition the surface of the catalyst 31 at predetermined timing. This conditioning section 60 is disposed outside the wafer Wf held by the substrate holding section 20. The catalyst 31 held by the catalyst holding section 30 can be disposed on the conditioning section 60 by the swing arm 50.

The control section 90 controls the overall operation of the substrate processing apparatus 10. The control section 90 also controls parameter relating to etching processing conditions of the wafer Wf. Examples of such parameters include (1) a contact load of the catalyst 31 on the wafer Wf, (2) a relative speed between the catalyst 31 and the water NW, for example, the number of revolutions of the substrate holding section 20, angular rotating speed, the number of revolutions of the catalyst holding section 30, various motion conditions such as swing speed of the swing arm 50, (3) a type of the processing liquid PL, (4) pH of the processing liquid PL, (5) a flow rate of the processing liquid PL, (6) a bias voltage to be applied to the catalyst 31, (7) a processing temperature, (8) a type of the catalyst. By adjusting these etching processing conditions, the etching processing speed can be adjusted. The control section 90 also controls parameters relating to conditioning conditions for the catalyst surface at the conditioning section 60,

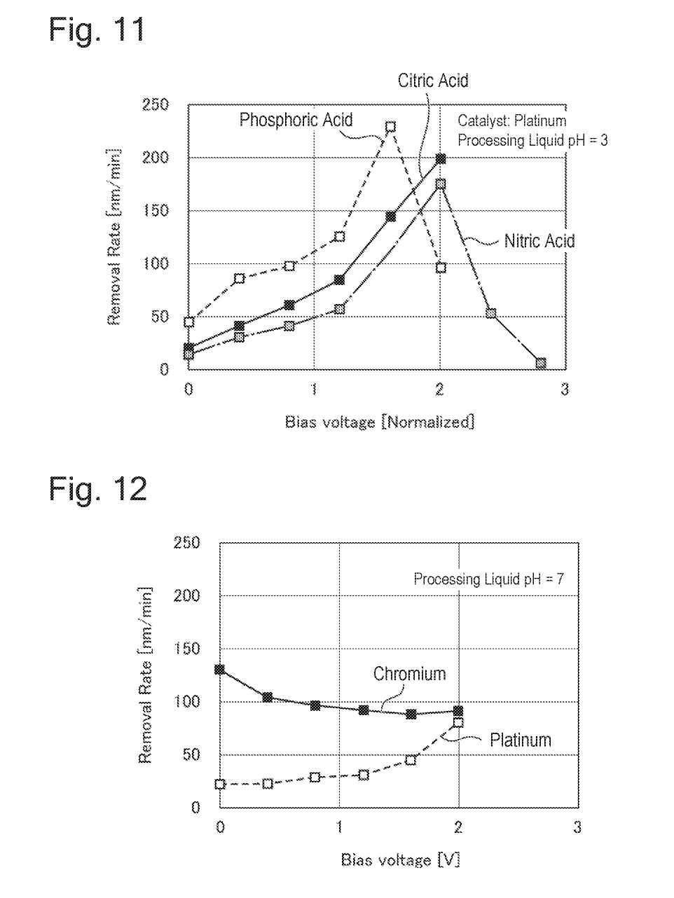

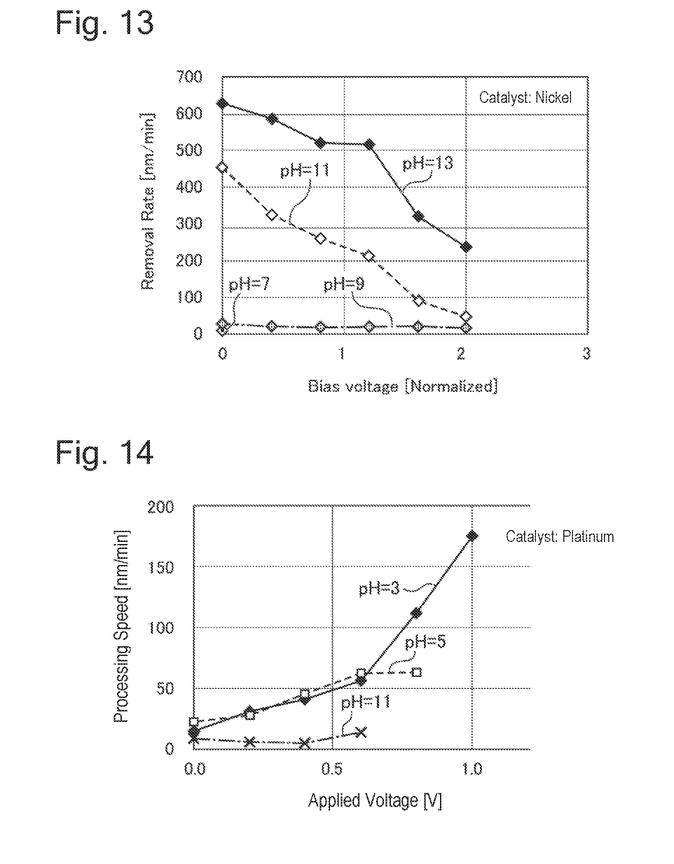

As the etching processing conditions, (1) by adjusting the contact load of the catalyst 31 on the wafer Wf, it is possible to adjust the contact area between the catalyst 31 and the wafer Wf to a certain degree. Since there are micro convex and concave portions on the surface of the catalyst 31, it is possible to increase the contact area between the catalyst 31 and the wafer Wf and increase the etching processing speed to a certain degree by increasing the contact load up to a certain range. (2) Adjusting the relative speed between the catalyst 31 and the wafer Wf improves input/output of the processing liquid PL between the catalyst 31 and the wafer Wf, and so increasing the relative speed up to a certain range can increase the etching processing speed. For example, the relative speed between the catalyst 31 and the wafer Wf can be adjusted by changing the number of revolutions of the catalyst holding section 30, rotation of the substrate holding section 20 and the swing speed of the swing arm 50. The number of revolutions of the catalyst holding section 30 or the substrate holding section 20 can be set to any number of revolutions between 0 rpm to 500 rpm, for example. Generally, an excessively high rotation speed may cause the processing liquid PL to be discharged out of the wafer Wf more readily, while an excessively low rotation speed may cause insufficient spreading of the processing liquid PL over the surface of the wafer Wf. The number of revolutions of the catalyst holding section 30 or the substrate holding section 20 is preferably set within a range of 10 rpm to 200 rpm. The swing speed of the swing arm 50 can be set to any speed between 0 mm/sec and 250 mm/sec, for example. According to the CARE method, the amount of processing (etching amount) of an object to be processed (wafer WO is proportional to an approaching or contacting time between the catalyst material and the object to be processed. Therefore, in an apparatus whose catalyst 31 is smaller in size than the wafer Wf, a change in the swing speed of the catalyst holding section 30 influences the processing speed and a distribution of the processing speed. For example, when the swing speed of the catalyst holding section 30 is small, since the contact time increases at a point at which the catalyst holding section 30 within the surface of the wafer Wf passes, the amount of processing of the wafer Wf increases. When the swing arm 50 is swung at a predetermined speed, a variation in the contact time of the catalyst holding section 30 within the surface of the object to be processed increases, and so the distribution of the processing speed within the surface of the object to be processed deteriorates. Therefore, by adjusting the swing speed in various regions within the surface of the wafer Wf as appropriate, it is possible to improve the processing speed and uniformity of the distribution of the processing speed within the surface simultaneously. (3) Since the etching speed changes depending on the type of the processing liquid FL, it is possible to adjust the etching speed by changing the type of the processing liquid PL. FIG. 11 is a graph illustrating an etching speed of an SiO₂ substrate when a voltage to be applied to the catalyst is changed using a platinum catalyst with various types of processing liquid PI, set to pH=3. As is clear from the graph in FIG. 11, the etching speed varies depending on the type of the processing liquid PL. (4) The etching speed can be adjusted also by adjusting pH of the processing liquid PL. FIG. 13 is a graph illustrating the etching speed of SiO₂ when a voltage to be applied to the catalyst is changed at various pHs of the processing liquid PL (potassium hydroxide solution) using a nickel catalyst. FIG. 14 is a graph illustrating the etching speed of SiO₂ when a voltage to be applied to the catalyst is changed at various pHs of the processing liquid PL (pH=3, 5 for citric acid and pH=11 for potassium hydroxide solution) using a platinum catalyst. As is clear from FIG. 13 and FIG. 14, the etching speed can be adjusted by changing pH of the processing liquid PL. (5) The input/output of the processing liquid PL between the catalyst 31 and the wafer Wf can be adjusted to a certain degree by adjusting the flow rate of the processing liquid PL, and so the etching speed can be adjusted to a certain degree. (6) The etching speed can be adjusted by adjusting a bias voltage applied to the catalyst. FIG. 12 is a graph illustrating the etching speed of SiO₂ when a voltage to be applied to the catalyst is changed with the processing liquid PL (pure water) set to pH=7 using a platinum catalyst and a chromium catalyst. As shown in the graphs in FIG. 11 to FIG. 14, the etching speed can be adjusted by changing the voltage to be applied to the catalyst. Note that more specifically, the voltage to be applied to the catalyst 31 can be changed by adjusting a voltage between the catalyst electrode 30-49 and the counter electrode 30-50 of the catalyst holding section 30 shown in FIG. 7. (7) The etching speed can be adjusted by adjusting a processing temperature during etching processing. For example, the etching speed can be adjusted by adjusting the temperature of the processing liquid PL and/or the temperature of the substrate holding section. More specifically, the temperature of the catalyst can be adjusted by the catalyst temperature control mechanism using the Peltier element 32-6 mentioned above in FIG. 8 and the temperature of the wafer Wf can be controlled by a substrate temperature control section 121 which will be described later. Alternatively, the temperature of the processing liquid PL may also be adjusted. (8) The etching speed can be adjusted by changing the type of catalyst. As the type of catalyst, for example, precious metal, transition metal, ceramics-based solid catalyst, basic solid catalyst, acidic solid catalyst or the like can be used.

FIG. 9 illustrates a schematic configuration of the substrate processing apparatus 110 as an embodiment. In FIG. 9, the same components as those shown in FIG. 2 are assigned the same reference numerals and description thereof is omitted. This aspect is also applicable to other drawings. In the substrate processing apparatus 110 according to the present embodiment, the substrate temperature control section 121 is disposed in the substrate holding section 120. The substrate temperature control section 121 is, for example, a heater and configured so as to control the temperature of the wafer Wf. The substrate temperature control section 121 adjusts the temperature of the wafer Wf to a desired temperature. Since the CARE method is chemical etching, the etching speed thereof depends on a substrate temperature. Such a configuration can change the etching speed according to the substrate temperature. As a result, it is possible to adjust the etching speed and a distribution within the surface thereof. Note that in the present embodiment, a plurality of heaters are arranged in a concentric form and the temperature of each heater may be adjusted, but a spiral shaped single heater may be arranged in the substrate holding section 120.

As an alternative aspect, the substrate processing apparatus 110 may be provided with a processing liquid temperature adjustment section that adjusts the temperature of the processing liquid PL to a predetermined temperature instead of or in addition to the substrate temperature control section 121. Alternatively, the catalyst holding section 30 may be provided with a catalyst temperature control mechanism that adjusts the temperature of the catalyst 31 instead of or in addition to them. For example, the Peltier element 32-6 described together with FIG. 8 can be used. The etching speed can be adjusted by adjusting the processing liquid temperature using these configurations, too. The temperature of the processing liquid PL may be adjusted to a predetermined temperature within a range of 10° C. or above to 60° C. or less, for example.

The etching performance can be stabilized by applying the above-described temperature dependency, for example, by disposing the substrate processing apparatus 110 in a thermostatic tank and controlling the temperature of the entire substrate processing apparatus 110.

Furthermore, in a processing state, different types of materials may be mixed and exposed on the substrate. Since the etching speed of the material varies depending on the type of the catalyst material, the etching speed may be changed by changing the catalyst material depending on the processing state. For example, as will be described later, the substrate processing apparatus 10 may be provided with a plurality of catalyst holding sections 30.

As an embodiment, the substrate processing apparatus 10 may also be provided with a mechanism for performing chemical mechanical polishing (CMP) in addition to the catalyst holding section 30. For example, as such a CMP mechanism, it is possible to provide a mechanism in which a CMP polishing pad equivalent in size to the catalyst holding section 30 according to the present disclosure is pressed against the wafer Wf through a mechanism similar to the swing arm 50 and the wafer Wf is polished while supplying a polishing liquid thereto. Since a conventional one can be used for the CMP mechanism, detailed description thereof is omitted here. In the present embodiment, polishing using the CMP mechanism and etching processing using the CARE method may be performed simultaneously or successively. Joint use of polishing using CMP and etching processing using the CARE method can improve the processing speed of the wafer Wf.

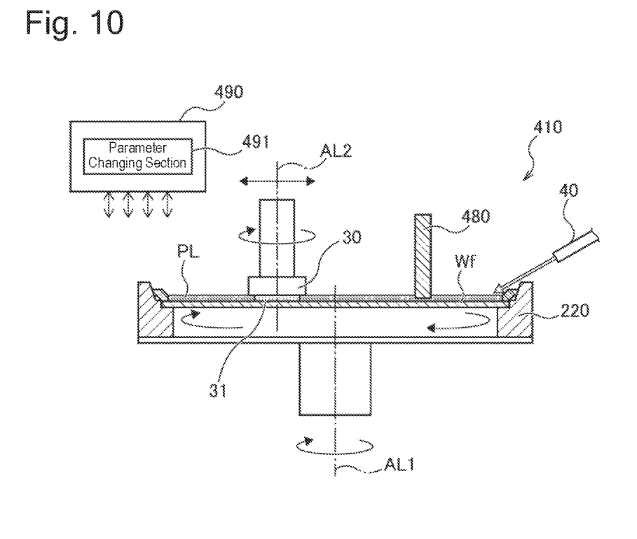

FIG. 10 illustrates a schematic configuration of a substrate processing apparatus 410 as an embodiment. The substrate processing apparatus 410 is provided with a monitoring section 480 and a control section 490 is provided with a parameter changing section 491. The monitoring section 480 monitors an etching processing state of a region to be processed of a wafer WE The monitoring section 480 is configured to be movable by an actuator to a specific position in the wafer Wf in the horizontal direction. Note that the monitoring section 480 may be fixed to a specific position or may move within the surface of the wafer Wf during etching processing. When the monitoring section 480 moves within the surface of the wafer WE the monitoring section 480 may be configured to move in coordination with the catalyst holding section 30. This makes it possible to grasp a distribution of an etching processing state within the surface of the wafer Wf. The configuration of the monitoring section 480 varies depending on the material of the region to be processed. Furthermore, when a region to be processed is formed of a plurality of materials, a plurality of monitoring sections may be used in combination. For example, when an object to be processed is a metal film formed on the wafer Wf, the monitoring section 480 may be configured as an eddy current monitoring section. More specifically, the monitoring section 480 passes a high frequency current into a sensor coil disposed in proximity to the surface of the wafer Wf to generate an eddy current in the wafer Wf and generate an induced magnetic field in a conductive metal film formed on the wafer Wf. Since the eddy current generated here and a joint impedance calculated thereby vary depending on the thickness of the metal film, the monitoring section 480 can monitor an etching processing state using such a change.

The monitoring section 480 is not limited to the aforementioned configuration but can be provided with various configurations. For example, when the object to be processed is a material having a light transmission property such as oxide film, the monitoring section 480 may radiate light toward a region to be processed of the wafer Wf and detect reflected light. More specifically, reflected light on the surface of the region to be processed of the wafer Wf and reflected light reflected after passing through the layer to be processed of the wafer Wf are superimposed one on another, and mutually interfering reflected light beams are received. Here, since the intensity of reflected light varies depending on the film thickness of layers to be processed, it is possible to monitor the etching processing state based on this change.

Alternatively, when the layer to be processed is a compound semiconductor GaN, SiC), the monitoring section 480 may use at least one of a photoelectric current scheme, a photoluminescent light scheme and a Raman light scheme. The photoelectric current scheme measures the value of a current flowing through a conductor that connects the wafer Wf and a metal wiring provided for the substrate holding section 20 when the surface of the wafer Wf is irradiated with excitation light to thereby measure the etching amount in the surface of the wafer Wf. The photoluminescent light scheme measures photoluminescent light emitted from the surface when the surface of the wafer Wf is irradiated with excitation light to thereby measure the etching amount in the surface of the wafer Wf. The Raman light scheme measures Raman light included in reflected light from the surface when the surface of the wafer Wf is irradiated with visible monochromatic light to thereby measure the etching amount in the surface of the wafer Wf.

Alternatively, the monitoring section 480 may also monitor the etching processing state based on a torque current of the drive section when the substrate holding section 220 and the catalyst holding section 30 relatively move. According to such an embodiment, it is possible to monitor a friction state caused by contact between the semiconductor material of the substrate and the catalyst via the torque current, and monitor the etching state through, for example, a change in the convexo-concave state of the semiconductor material on the surface to be processed and a change in the torque current caused by exposure of another material.

As an embodiment, the monitoring section 480 can be a vibration sensor provided for the catalyst holding section 30. Vibration when the substrate holding section 220 and the catalyst holding section 30 relatively move is detected using the vibration sensor. When the convexo-concave state of the wafer Wf varies or another material is exposed during processing of the wafer Wf, the vibration state changes when the state of friction between the wafer Wf and the catalyst 31 changes. By detecting this vibration change using the vibration sensor, the wafer Wf processing state can be detected.

The etching processing state monitored in this way is reflected by the parameter changing section 491 in the processing of the wafer being processed by the substrate processing apparatus 10 or the next wafer Wf. More specifically, the parameter changing section 491 changes control parameters relating to etching processing conditions for the wafer being processed or the next water based on the etching processing state monitored by the monitoring section 480. For example, the parameter changing section 491 changes the control parameters based on a difference between a thickness distribution of a layer to be processed obtained based on the monitoring result of the monitoring section 480 and a predetermined target thickness distribution in such a way that the difference becomes smaller. According to such a configuration, it is possible to feed back the monitoring result of the monitoring section 480 and improve etching characteristics in processing of the water being processed or the next wafer.

The control section 490 may feed back the monitoring result of the monitoring section 480 to the processing of the wafer Wf being processed. For example, the monitoring section 480 may change parameters within the processing conditions of the substrate processing apparatus 10 during processing so that the difference between the thickness distribution of the region to be processed obtained based on the monitoring result of the monitoring section 480 and a predetermined target thickness distribution falls within a predetermined range (ideally 0). Note that the monitoring result obtained in the monitoring section 480 can be made to function not only as feedback to the aforementioned processing condition but also as an end point detection section for detecting an end point of the processing.

In the substrate processing apparatus 10 as an embodiment, the catalyst 31 is provided with individual catalysts of two or more types. As an alternative aspect, the catalyst 31 may be a mixture of two types of catalysts (e.g., alloy) or compound (e.g., intermetallic compound). According to such a configuration, when surfaces to be processed of two or more different types of materials are formed according to regions of the wafer Wf, it is possible to etch the wafer Wf uniformly or at a desired selection ratio. For example, when a Cu layer is formed in a first region of the wafer Wf and an SiO₂ layer is formed in a second region, the catalyst 31 may be provided with a region made of a Cu acidic solid catalyst and a region made of SiO₂ platinum. In this case, Cu ozone water and SiO₂ acid may be used for the processing liquid PL. Alternatively, when a group III-V metal (e.g., GaAs) layer is formed in the first region of the wafer Wf and an SiO₂ layer is formed in the second region, the catalyst 31 may be provided with a region made of iron for the group III-V metal and a region made of SiO₂ platinum or nickel. In this case, group III-V metal ozone water and SiO₂ acid may be used for the processing liquid PL.

In this case, the substrate processing apparatus 10 may be provided with a plurality of catalyst holding sections 30. The plurality of catalyst holding sections 30 may respectively hold catalysts of different types. For example, the first catalyst holding section 30 may hold the catalyst 31 made of an acidic solid catalyst and the second catalyst holding section 30 may hold the catalyst 31 made of platinum. In this case, the two catalyst holding sections 30 may be configured to scan only the layer of the corresponding material on the wafer WE According to such a configuration, more efficient processing can be performed by sequentially or simultaneously using the first catalyst holding section 30 and the second catalyst holding section 30 and supplying a processing liquid PL corresponding to the catalyst holding section 30 used. As a result, it is possible to improve processing capability per unit time.

As an alternative aspect, processing liquids PL of different types may be sequentially supplied. According to such a configuration, when surfaces to be processed of different materials of two or more types are formed according to regions of the wafer Wf, it is possible to etch the wafer Wf uniformly or at a desired selection ratio. For example, the catalyst holding section 30 may hold a catalyst made of platinum. The substrate processing apparatus 10 may supply a neutral solution or a solution containing Ga ions as the processing liquid PL, etch the group III-V metal layer of the wafer Wf, and then supply an acid as the processing liquid PL to etch the SiO₂ layer of the wafer Wf.

As a further alternative aspect, the substrate processing apparatus 10 may be provided with a plurality of catalyst holding sections 30 holding a catalyst of the same type. In such a case, the plurality of catalyst holding sections 30 may be used simultaneously. According to such a configuration, it is possible to improve processing capability per unit time.

A basic flow of etching processing of a substrate by the present substrate processing apparatus 10 will be described. A wafer Wf from the substrate transporting section is held by the substrate holding section 20 through vacuum suction. Next, a processing liquid PL is supplied from the processing liquid supply section 40. Next, after the swing arm 50 places the catalyst 31 in the catalyst holding section 30 at a predetermined position on the wafer Wf, upward/downward movement of the catalyst holding section 30 causes the region to be processed of the wafer Wf to come into contact with the catalyst 31 and the contact pressure therebetween is adjusted to a predetermined contact pressure. Relative movement between the substrate holding section 20 and the catalyst holding section 30 starts simultaneously or after contact with the present contact operation. Such relative movement is realized through rotation of the substrate holding section 20, rotation of the catalyst holding section 30 and swing motion of the swing arm 50 in the present embodiment. Note that the relative movement between the substrate holding section 20 and the catalyst holding section 30 can be realized by at least one of rotating motion, translation motion, arcuate motion, reciprocating motion, scrolling motion, angular rotating motion (rotating motion by a predetermined angle less than 360 degrees) of at least one of the substrate holding section 20 and the catalyst holding section 30.

In such an operation, an etchant generated by catalytic action of the catalyst 31 acts on the surface of the wafer Wf at a location of contact between the wafer Wf and the catalyst 31, and the surface of the wafer Wf is thereby removed by etching. The region to be processed of the wafer Wf can be formed of any one or a plurality of material(s), and examples of such a region to be processed include an insulating film represented by SiO₂ or Low-k material, wiring metal represented by Cu or W, barrier metal represented by Ta, Ti, TaN, TiN or Co and group ill-V material represented by GaAs. Examples of the material of the catalyst 31 may include precious metal, transition metal, ceramics-based solid catalyst, basic solid catalyst, acidic solid catalyst. Furthermore, examples of the processing liquid PL may include oxygen-dissolved water, ozone water, acid, alkaline solution, H₂O₂ water, hydrofluoric acid solution. Note that the catalyst 31 and the processing liquid PL can be set as appropriate according to the material of the region to be processed of the wafer Wf. For example, when the material of the region to be processed is Cu, an acidic solid catalyst may be used as the catalyst 31 and ozone water may be used as the processing liquid PL. On the other hand, when the material of the region to be processed is SiO₂, platinum or nickel may be used as the catalyst 31 and acid may be used as the processing liquid PL. When the material of the region to be processed is a group III-V metal (e.g., GaAs), iron may be used as the catalyst 31 and H202 water may be used as the processing liquid. PL.

When there are a plurality of materials to be etched in the region to be processed of the wafer Wf, a plurality of catalysts and a plurality of processing liquids PL may be used for individual materials. Examples of specific operations on the catalyst side include (1) operation by one catalyst holding section where a plurality of catalysts are arranged and (2) operation by a plurality of catalyst holding sections where different catalysts are arranged respectively. In (1), a mixture or compound containing a plurality of catalyst materials may be used. With regard to the processing liquid side, when the catalyst side corresponds to mode (1), a mixture of components suitable for etching of the material to be etched by individual catalyst materials may be used as the processing liquid PL. When the catalyst side corresponds to mode (2), a processing liquid PL suitable for etching of the material to be etched may be supplied to the vicinity of the respective catalyst holding sections.

In the present embodiment, since the catalyst 31 is smaller than the wafer Wf, when etching is applied to the entire surface of the wafer Wf, the catalyst holding section 30 swings over the entire surface of the wafer Wf. According to the CARE method, since etching takes place only at the part contacting the catalyst, the distribution within the wafer surface of the contact time between the wafer Wf and the catalyst 31 greatly influences the distribution within the wafer surface of the etching amount. In this respect, it is possible to make the distribution of the contact time uniform by making the swing speed of the swing arm 50 within the wafer surface variable. More specifically, the swing range of the swing arm 50 within the wafer Wf surface is divided into a plurality of sections and the swing speed is controlled at each section.

According to the substrate processing apparatus 10 using the CARE method described so far, etching takes place only at a location of contact between the wafer Wf and the catalyst 31, while no etching takes place at locations other than the location of contact between the wafer Wf and the catalyst 31. Thus, only convex portions of the wafer Wf including convex and concave portions are selectively chemically removed, and it is thereby possible to perform flattening processing. Since the wafer Wf is chemically processed, the processing surface of the wafer Wf is hardly damaged. Note that the wafer Wf and the catalyst 31 theoretically need not always contact each other and they may be located in proximity to each other. In this case, “proximity” can be defined to be as close as the etchant generated by catalytic reaction can reach the region to be processed of the wafer Wf. The distance between the wafer Wf and the catalyst 31 can be set to be, for example, 50 nm or less.

Hereinafter, an embodiment of a substrate processing method using the aforementioned substrate processing apparatus and substrate processing system will be described.

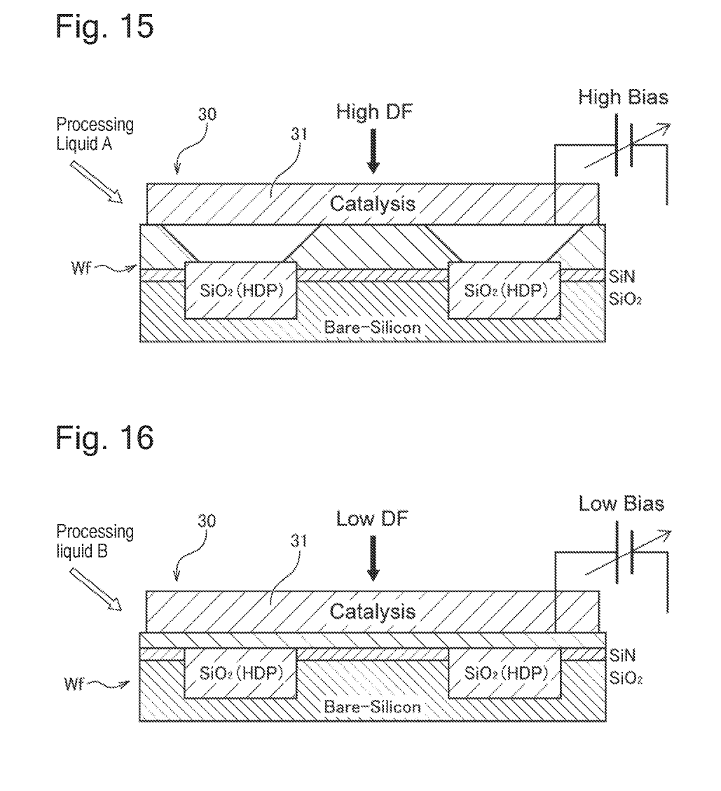

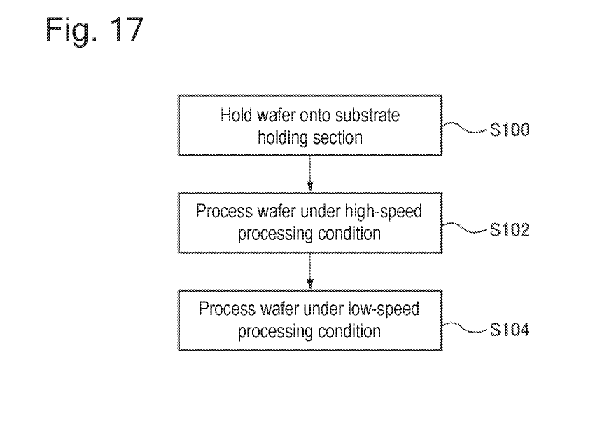

FIG. 15 and FIG. 16 are schematic cross-sectional views illustrating substrate processing as an embodiment. FIG. 15 and FIG. 16 illustrate part of a flattening process in an STI step. FIG. 15 is a schematic side view illustrating a state of an initial stage of the flattening process. As shown in FIG. 15, an SiO₂ film having steps on its surface is formed on the flattened wafer Wf. In the example in FIG. 15, the wafer Wf is etched until the steps of the stepped. SiO₂ are eliminated and the underlying SiN layer is exposed. FIG. 17 is a diagram illustrating a processing flow of the STI step shown in FIG. 15 and FIG. 16.

In the flattening initial process shown in FIG. 15, the wafer Wf is held by the substrate holding section 20 (S100). The SiO₂ steps are etched from the wafer W held by the substrate holding section 20 as fast as possible S102). Specific processing parameters such as (1) a contact load of the catalyst 31 on the wafer Wf, (2) a relative speed between the catalyst 31 and the wafer Wf, (3) a type of the processing liquid. PI, (4) pH of the processing liquid PL. (5) a flow rate of the processing liquid PL, (6) a bias voltage to be applied to the catalyst 31, (7) processing temperature, and (8) a type of the catalyst or the like are adjusted so that the etching speed increases. As an example, the processing parameters are set as follows: contact load: 210 hPa, relative speed: 0.4 m/s, type of processing liquid: citric acid solution, pH of processing liquid: 3, flow rate of processing liquid: 500 mL/min, bias voltage: +1.0 V, processing temperature: 50° C., type of catalyst: platinum.

Note that the processing liquid PL may be supplied from the outside of the catalyst holding section 30 as shown in FIGS. 1 and 2 or may be supplied from the inside of the catalyst holding section as shown in FIG. 7. Moreover, a bias voltage may be applied to the catalyst 31. More specifically, a predetermined voltage can be applied between the catalyst electrode 30-49 and the counter electrode 30-50 in the catalyst holding section shown in FIG. 7.

The situation after the SiO₂ steps of the wafer Wf are eliminated becomes as shown in FIG. 16. FIG. 16 is a schematic side view illustrating a final state of the flattening process. Note that the elimination of the SiO₂ steps can be detected by the aforementioned monitoring section 480. Alternatively, the elimination of the SiO₂ steps may be determined based on the lapse of a predetermined processing time. In the final stage of the flattening process shown in FIG. 16, since the SiO₂ film becomes as thin as the SiN film to be exposed, etching processing is preferably performed at a lower speed than at the initial stage of the process until the SiN film is completely exposed. Therefore, the processing parameters are changed so that etching is performed at a lower speed than at the initial stage of the process (S104). As an example, the processing parameters are set as follows: contact load: 70 hPa, relative speed: 0.1 m/s, type of the processing liquid: potassium hydroxide solution, pH of processing liquid: 11, flow rate of the processing liquid: 100 mL/min, bias voltage: 0 V, processing temperature: 20° C., type of the catalyst: platinum.

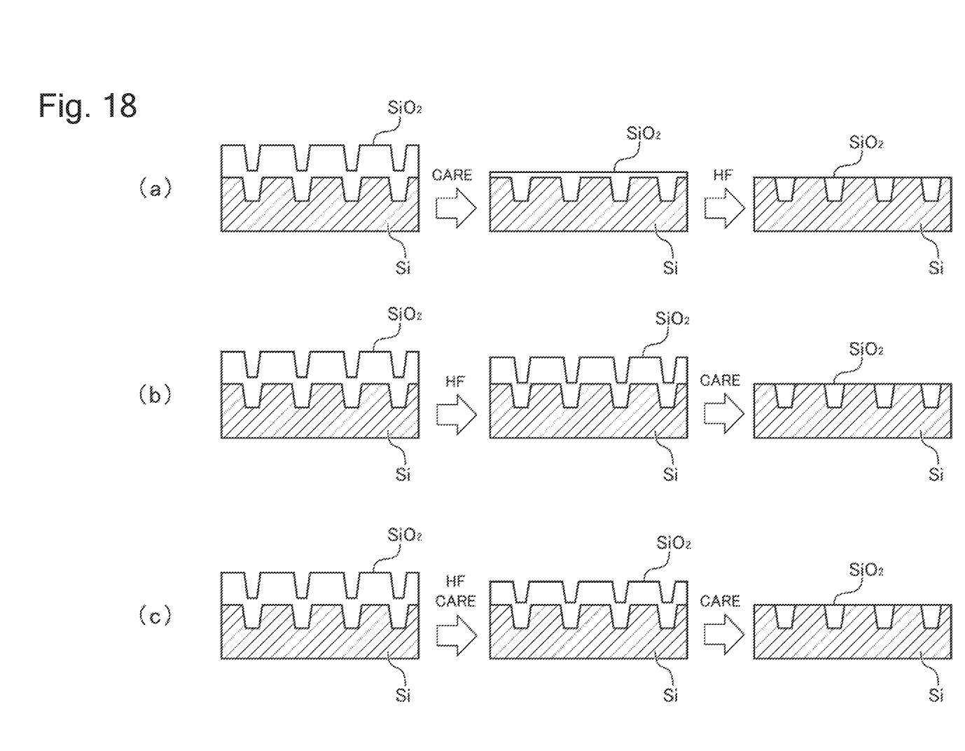

FIG. 18 is a diagram illustrating another example where the etching processing condition is changed during processing of the wafer Wf and etching processing is performed on the wafer Wf. The example shown in FIG. 18 is an example of a case where a stepped SiO₂ film is formed on Si and SiO₂ is removed by etching until the SiO₂ steps are eliminated and the Si surface is exposed.

In the example in FIG. 18(c), SiO₂ is isotropically etched using a hydrofluoric acid solution (HF) first, and the SiO₂ steps are eliminated using the CARE method at the same time. At this time, etching of the hydrofluoric acid solution is performed until the bases of the grooves of SiO₂ become as high as the Si surface. Then, etching of the hydrofluoric acid solution is finished and the remaining steps are eliminated using only the CARE method. Since the etching speed of SiO₂ using the hydrofluoric acid solution is higher than the etching speed using the CARE method, it is possible to complete the process in a shorter time than using only the CARE method by simultaneously performing isotropic etching using the hydrofluoric acid solution and step elimination using the CARE method.

In the example in FIG. 18(c), although etching using the hydrofluoric acid solution and step elimination using the CARE method are performed simultaneously, they may be performed successively as shown in FIG. 18(a) and FIG. 18(b) respectively. This makes it possible to prevent deterioration of processing performance caused by mixing of the hydrofluoric acid solution and the solution used in the CARE method, which would produce reaction products and thereby produce scratches.

In the example in FIG. 18(a), the SiO₂ steps are eliminated using the CARE method first and the SiO₂ film is thereby flattened. After that, SiO₂ is isotropically etched using the hydrofluoric acid solution (HF) and Si is exposed. By applying etching using the hydrofluoric acid solution lastly, it is possible to further reduce damage on the surface to be processed that could be generated by the catalyst contacting the surface to be processed,

In the example in FIG. 18(b), SiO₂ is isotropically etched using the hydrofluoric acid solution (HF) first. At this time, SiO₂ is etched using the hydrofluoric acid solution until the bases of the grooves of SiO₂ become as high as the Si surface. After that, the SiO₂ steps are eliminated using the CARE method and Si is exposed. By eliminating the steps using the CARE method lastly, it is possible to apply the method of monitoring the etching processing state based on a torque current of the drive section when the substrate holding section 220 and the catalyst holding section 30 move relatively.

Note that in the example shown in FIG. 18, when the CARE method is performed, the etching processing condition may be changed midway through as described above.

The embodiments of the present invention have been described so far, but the present invention is by no means limited to the aforementioned embodiments. The respective features of the foregoing embodiments can be combined or interchanged with each other unless they are mutually contradictory.

[Aspect 1] According to aspect 1, a method is provided whereby a substrate and a catalyst are caused to contact each other in the presence of a processing liquid to process the substrate. Such a method includes a step of processing the substrate under a predetermined processing condition for processing the substrate at a high speed and a step of changing the processing condition so as to process the substrate at a low speed during processing of the same substrate. According to such an aspect, when films to be processed differ at an initial state and at a final stage of the substrate processing process or when process requirements differ, the substrate can be processed under optimum conditions respectively.

[Aspect 2] According to aspect 2, in the method of aspect 1, the step of changing the processing condition includes a step of changing at least one of (1) a contact load of the catalyst on the substrate, (2) a relative speed between the catalyst and the substrate, (3) a type of the processing liquid, (4) pH of the processing liquid, (5) a flow rate of the processing liquid, (6) a bias voltage to be applied to the catalyst, (7) a processing temperature, and (8) a type of the catalyst. According to such an aspect, it is possible to realize appropriate substrate processing conditions by changing various processing condition parameters.

[Aspect 3] According to aspect 3, the method according to aspect 1 or aspect 2 further includes a step of monitoring a processing state of a substrate being processed and a step of changing the processing condition in accordance with the processing state of the substrate. According to such an aspect; it is possible to change the processing condition of the substrate at optimum timing in accordance with the processing state of the substrate.

[Aspect 4] According to aspect 4, the method according to any one of aspects 1 to 3 further includes a step of changing the processing condition when a predetermined time elapses after processing on the substrate wider the predetermined processing condition starts. According to such an aspect, by determining timing for changing a high-speed processing condition to a low-speed processing condition based on, for example, an experiment in advance, it is possible to process the substrate under an optimum condition without monitoring the processing state of the substrate being processed. It is also possible to monitor the processing state of the substrate being processed and change the processing condition after a predetermined time elapses and/or when a predetermined processing state is reached.

[Aspect 5] According to aspect 5, the method according to any one of aspects 1 to 4 further includes a step of polishing the substrate through chemical mechanical polishing.

[Aspect 6] According to aspect 6, a method is provided whereby a substrate is processed by causing an SiO₂ containing substrate and a catalyst to contact each other in the presence of a processing liquid. Such a method includes a step of supplying a hydrofluoric acid solution to a surface of the substrate and etching SiO₂ in the substrate with the hydrofluoric acid solution. According to such an aspect, it is possible to jointly use isotropic etching with the hydrofluoric acid solution and etching using the catalyst and the processing liquid, and thereby speedily process the substrate.

The present application claims a priority based on Japanese Patent Application No. 2015-145960, filed on Jul. 23, 2015. The disclosure of Japanese Patent Application No. 2015-145960 including the specification, the scope of claims, drawings and abstract is incorporated herein by reference in its entirety. The disclosures of Japanese Patent Application Laid-Open No. 2008-121099 (PTL 1). Japanese Patent Application Laid-Open No. 2008-136983 (PTL 2), Japanese Patent Application Laid-Open No. 2008-166709 (PTL 3), Japanese Patent Application Laid-Open No. 2009-117782 (PTL 4), and WO 013/084934 (PTL 5) including the specifications, the scopes of claims, drawings and abstracts are incorporated herein by reference in their entirety.

### REFERENCE SIGNS LIST

10 . . . Substrate processing apparatus
20 . . . Substrate holding section
21 . . . Wall portion
30 . . . Catalyst holding section
30-40 . . . Processing liquid supply passage
30-42 . . . Supply port
30-49 . . . Catalyst electrode
30-50 . . . Counter electrode
30-52 . . . Wall portion
30-70 . . . Disk holder part
30-72 . . . Catalyzer disk part
30-74 . . . Head
30-76 . . . Contact probe
31 . . . Catalyst
40 . . . Processing liquid supply section
50 . . . Swing arm
60 . . . Conditioning section
90 . . . Control section
480 . . . Monitoring section
491 . . . Parameter changing section
Wf . . . Wafer
PL . . . Processing liquid

1. A method for processing a substrate while bringing a catalyst into contact with the substrate in the presence of a processing liquid, the method comprising:
a step of processing the substrate under a predetermined processing condition for processing the substrate at a high speed; and
a step of changing the processing condition so as to process the substrate at a low speed during processing of the same substrate.

2. The method according to claim 1, wherein the step of changing the processing condition comprises a step of changing at least one of (1) a contact load of the catalyst on the substrate, (2) a relative speed between the catalyst and the substrate, (3) a type of the processing liquid, (4) pH of the processing liquid, (5) a flow rate of the processing liquid, (6) a bias voltage to be applied to the catalyst, (7) a processing temperature, and (8) a type of the catalyst.

3. The method according to claim 1, wherein the method further comprises:
a step of monitoring a processing state of the substrate being processed; and
a step of changing the processing condition in accordance with the processing state of the substrate.

4. The method according to claim 1, wherein the method further comprises a step of changing the processing condition when a predetermined time elapses after processing of the substrate under the predetermined processing condition starts.

5. The method according to claim 1, wherein the method further comprises a step of polishing the substrate through chemical mechanical polishing.

6. A method for processing a substrate while bringing a catalyst into contact with the substrate containing SiO₂ in the presence of a processing liquid, the method comprising a step of supplying a hydrofluoric acid solution to a surface of the substrate and etching SiO₂ of the substrate using the hydrofluoric acid solution.
